(19) United States
(12) Patent Application Publication
(10) Pub. No.: US 2018/0366352 A1
(43) Pub. Date: Dec. 20, 2018

(54) METHOD AND DEVICE FOR THE THERMAL TREATMENT OF SUBSTRATES AND HOLDING UNIT FOR SUBSTRATES

(71) Applicant: CENTROTHERM INTERNATIONAL AG, Blaubeuren (DE)

(72) Inventors: Steffem Müller, Ulm (DE); Helmut Aschner, Beimerstetten (DE); Thomas Keller, Senden (DE); Wilhelm Kegel, Laichingen (DE); Wilfried Lerch, Dornstadt-Tomerdingen (DE)

(21) Appl. No.: 16/061,034

(22) PCT Filed: Dec. 2, 2016
(86) PCT No.: PCT/EP2016/079628

§ 371 Date: Jun. 11, 2018

(30) Foreign Application Priority Data
Dec. 10, 2015 (DE) 10 2015 016 002.8

(51) Int. Cl. H01L 21/67; H01L 21/687; F27D 5/00; F27B 17/00

(52) U.S. Cl. CPC H01L 21/67115; H01L 21/68742; F27B 17/0025; H01L 21/68785; F27D 5/0037; H01L 21/6875

(57) ABSTRACT

The invention relates to a method and to a device for the thermal treatment of substrates, in particular semiconductor wafers, and to a holding unit for substrates. In the method, in a process unit having a process chamber and having a plurality of radiation sources, one or more substrates are held in a box having a lower part and having a cover, wherein the lower part and the cover form a holding space for the substrate therebetween. Furthermore, the following steps are performed in the method: loading the box and the substrate into the process chamber and closing the process chamber; purging the holding space of the box with a purging gas and/or a process gas before the box and the substrate contained therein are heated to a desired process temperature in order to establish a desired atmosphere inside the box; and heating the box and the substrate contained therein to the desired process temperature by means of thermal radiation emitted by the radiation sources. The holding unit for substrates is designed to support the substrates in a process unit having a process chamber and having a plurality of radiation sources. The holding unit has a lower part and a cover, which form a box therebetween in the closed state, said box having a holding space for the substrate, wherein at least one of the parts has a plurality of purging openings, which connect a periphery of the box to the holding space in order enable the purging of the holding space in the closed state of the box, wherein the purging openings are designed in such a way that the purging openings substantially prevent the passage of thermal radiation of the radiation sources.

### RELATED APPLICATIONS

This application corresponds to PCT/EP2016/079628, filed Dec. 2, 2016, which claims the benefit of German Application No. 10 2015 016 002.8, filed Dec. 10, 2015, the subject matter of which are incorporated herein by reference in its entirety.

### BACKGROUND OF THE INVENTION

The present invention relates to a method and an apparatus for the thermal treatment of substrates and to a receiving unit for substrates for receiving substrates during the thermal treatment thereof.

In the semiconductor technology, different apparatuses for the thermal treatment of semiconductor substrates are known. In particular, it is known to heat semiconductor substrates during the thermal treatment by means of electromagnetic radiation (heating radiation). Such radiation-based apparatuses are known in the art, for example, as RTP (RTP=rapid thermal processing) systems, RTA (RTA=rapid thermal anneal) systems or as rapid heating systems. Within such rapid heating systems, very rapid heating cycles can be provided, however the substrates to be processed are at least partially transparent to the heating radiation, in particular at low temperatures. Only at higher temperatures is a higher absorption is achieved. In addition, it is also known that certain substrates are sensitive to the heating radiation and therefore a direct radiant heating is not appropriate for such substrates. Also, structures on the substrate may provide different absorption properties across the substrate, such that radiant heating would result in inhomogeneous heating.

Therefore, in the past in some cases, plate elements have been used which were placed between the radiation sources and the substrate to be treated and in close proximity to the substrate. This made it possible to heat the plate element via radiation from the radiation sources and to thus indirectly heat the substrates via the radiation. However, the plate elements had the disadvantage that some radiation could still reach the substrate by simple or multiple reflections. This in turn could again lead to an inhomogeneous heating of the substrate. Therefore, attempts have also been made, instead of using the plate elements, to use a receiving unit with a base portion and a cover, which in the closed state formed a box with a receiving space for the substrate. This box was completely closed and no radiation from the radiation sources could get to the substrate.

Such closed box systems were each loaded outside the process chamber of the apparatus and then introduced in the loaded state into the process chamber of the apparatus. However, this caused the problem that the atmosphere within the closed box could only be adjusted rather inaccurate because the box was transported through the atmosphere before being loaded. Especially longer storage periods between the loading of the substrate into the box and the subsequent thermal treatment could lead to changes in the atmosphere within the box, and especially to an undesirably high oxygen concentration, which is particularly disadvantageous in WBG (Wide Band Gap) substrates.

### SUMMARY OF THE INVENTION

The present invention is therefore based on the object to overcome at least one of the aforementioned disadvantages of the prior art.

According to the invention, a method for the thermal treatment of substrates according to claim 1, a receiving unit for substrates according to claim 7 or an apparatus for the thermal treatment of substrates according to claim 11 is provided.

The method for the thermal treatment of substrates, in particular semiconductor wafers, takes place in a process unit having a process chamber and a plurality of radiation sources, wherein the substrate to be treated is accommodated in a box having a base and a cover forming a receiving space for the substrate therebetween. In the method, the box and the substrate are loaded into the process chamber which is subsequently closed. Thereafter, the receiving space of the box is purged with at least one of a purge gas and a process gas prior to heating the box and the substrate therein to a desired process temperature in order to set a desired atmosphere within the box. Only after purging the box and the substrate received therein are heated to the desired process temperature by means of thermal radiation emitted by the radiation sources. The method thus provides a purging of the interior of the box within the process chamber, in which subsequently and directly after the purging, the thermal treatment can be carried out by means of thermal radiation. This allows a desired atmosphere to be adjusted within the box. In particular, oxygen can be purged out, which is for example required for the thermal treatment of wide band gap (WBG) semiconductor substrates. Such substrates require the absence of oxygen during the thermal treatment in the range of less than 10 ppm O₂ in an otherwise inert gas environment. But also with other substrates, an exact adjustment of the atmosphere directly surrounding the substrate may be desired or required.

According to one embodiment of the invention, the box has a plurality of purge openings which connect a circumference of the box to the receiving space to permit purging of the receiving space in the closed state of the box, the purge openings being configured to prevent the passage of thermal radiation emitted by the radiation sources. Thus, a purging in the closed state of the box is possible and apparatuses for opening the box within the process chamber may be dispensed with. Alternatively or additionally, it is also possible that for purging the receiving space, the box is opened within the process chamber and the substrate is optionally lifted up from the base of the box to allow a good purging of the box and in particular to adjust a desired atmosphere in the immediate vicinity of the substrate during the thermal treatment. If, in addition to the purge openings, an opening device for the box is also provided, it is possible to, for example, first purge the box in the open state and also pass a gas through the box during the thermal treatment while the box is in the closed state in order to further purge the box during the thermal treatment and/or to provide an adjustment of a process gas atmosphere. According to one embodiment, the base has a substantially flat configuration with a plurality of support pins to support a substrate spaced from the upper surface of the base, and the cover has a recess in its lower surface in which the substrate is received in the closed state of the box. Such a configuration is particularly advantageous in order to allow good purging of the gap between the base and the substrate even without lifting the substrate, while the boy is in the open state. Furthermore, openings for allowing lift pins to pass therethrough in the region of the substrate can be dispensed with in order to provide a completely closed receiving space. For loading and unloading of the substrate, a suitable gripper could be inserted between the base and the substrate, or a suitable gripper could grip the substrate at the edges.

The purging preferably comprises at least one purging cycle comprising evacuating the process chamber to a negative pressure and subsequently introducing at least one of a purging and a process gas. By initially evacuating the process chamber and thus also the receiving space within the box to a negative pressure, undesired gas constituents can first be pumped away, wherein the subsequent introduction of at least one of a purge gas and a process gas can better purge or flush the atmosphere within the receiving space. Preferably, the method comprises a plurality of such purge cycles to ensure the desired adjustment of the atmosphere within the receiving unit.

The receiving unit for substrates, in particular semiconductor wafers, is suitable for supporting the substrates in an apparatus for thermally treating substrates having a process chamber and a plurality of radiation sources, the receiving unit having a base and a cover, which in the closed state form a box with a receiving space for the substrate therebetween. At least one of the parts (i.e. the base or the cover) has a plurality of purge openings connecting a circumference of the box to the receiving space to allow purging of the receiving space in the closed state of the box, wherein the purge openings are configured to in substance prevent passage of thermal radiation emitted by the radiation sources. Such a receiving unit allows the advantages already mentioned above. The purge openings preferably have a length which is at least three times longer than the width or height thereof. Alternatively or additionally, the purge openings may not extend linearly and, in particular, may have a Y configuration in order to prevent the passage of thermal radiation. A Y configuration may in particular provide a good distribution of the purge gas or the process gas in the region above and below a substrate received in the receiving space. In a further embodiment, the base and the cover have complementary, circumferential structures (with the exception of the purge openings) in such a way that they engage each other in the closed state and/or one of the base and the cover has a structure radially surrounding the other of the cover and the base to provide a good sealing of the receiving space relative to the process chamber.

The apparatus for the thermal treatment of substrates, in particular semiconductor wafers, has a process chamber and a plurality of radiation sources. The apparatus further comprises a receiving unit comprising a base and a cover, which, when closed, form a box with a receiving space for the substrate therebetween, and a support unit for supporting the box in the process chamber. At least one of the parts of the receiving unit has a plurality of purge openings, which connect a circumference of the box to the receiving space to allow purging of the receiving space in the closed state of the box, wherein the purge openings are configured so as to substantially prevent the passage of thermal radiation emitted by the radiation sources and/or the apparatus has a unit for opening the receiving unit within the process chamber to allow purging of the receiving space within the process chamber. Both alternatives allow the advantages already mentioned above. In particular, the receiving unit may be of the type described above. Alternatively, it is also possible that the receiving unit has no purge openings and substantially forms a closed unit which seals the receiving space relative to the process chamber. Such completely closed boxes, which are opened only for the purge process within the process chamber, are for example advantageous for GaAs semiconductor wafers. With such substrates an appropriate As vapor pressure should be achieved in the receiving space during the thermal treatment thereof, in order to prevent out diffusion of As from the GaAs substrate. Thus, a macro-gas environment should be adjusted in the receiving space. In order to promote this adjustment of a macro-gas environment, at least one of the base and the cover of the receiving unit can additionally be saturated with arsenic before the (first) use, in order to be able to also provide As for adjusting a respective vapor pressure during the thermal treatment.

The provision of at least one of special purge openings and an opening unit for the receiving unit in the process chamber allows a rapid purging of the receiving space and prevents dead volumes within the receiving space.

Preferably, the base and the cover have complementary circumferential structures in such a way that they engage one another in the closed state and/or in such a way that one structure radially surrounds the other. In this way, a good sealing of the receiving space can be achieved.

The method and apparatus for thermal treatment of substrates, as well as the receiving unit are particularly suitable for the thermal treatment of WBG (Wide Band Gap) substrates that do not show sufficient absorption for a direct absorption of radiation emitted by the radiation sources. Possible treatments include metallization annealing, activation of dopants or other processes. Heating of the substrates takes place indirectly via the receiving unit, which is heated by means of radiation. The thermal energy absorbed by the receiving unit is transmitted to the substrate primarily by convection (in the case of atmospheric pressure treatment) and/or radiation emitted by the receiving unit, which differs from the radiation emitted by the radiation sources (in particular in vacuum processes). Especially with WBG substrates, an oxygen-free environment in the range of less than 10 ppm O₂ is required, which can be achieved via the purging/flushing option of the receiving unit. But also for other substrates, the controlled purging of a receiving space within the receiving unit may be advantageous.

### BRIEF DESCRIPTION OF THE DRAWINGS

The invention will be explained in more detail herein below with reference to the drawings. In the drawings:

FIG. 1 shows a schematic cross-sectional view through an apparatus for thermally treating substrates having a receiving unit according to the present invention received therein, the receiving unit being sown in a closed state;

FIG. 2 shows a schematic cross-sectional view of an apparatus for thermally treating substrates similar to FIG. 1, but with the receiving unit shown in an open state;

FIG. 3 shows a schematic top view onto a base of the receiving unit according to FIG. 1;

FIG. 4 shows a schematic plan view of an alternative base of the receiving unit;

FIG. 5 shows a further alternative embodiment of a base of the receiving unit;

FIGS. 6a and 6b show an alternative receiving unit according to the invention, wherein FIG. 6a shows the receiving unit in an open state and FIG. 6b shows the receiving unit in the closed state.

### DESCRIPTION

Locational or directional references, as used in the following description primarily refer to the illustration in the drawings and therefore should not be taken as limiting the scope of the application. However, they can also refer to a preferred final arrangement.

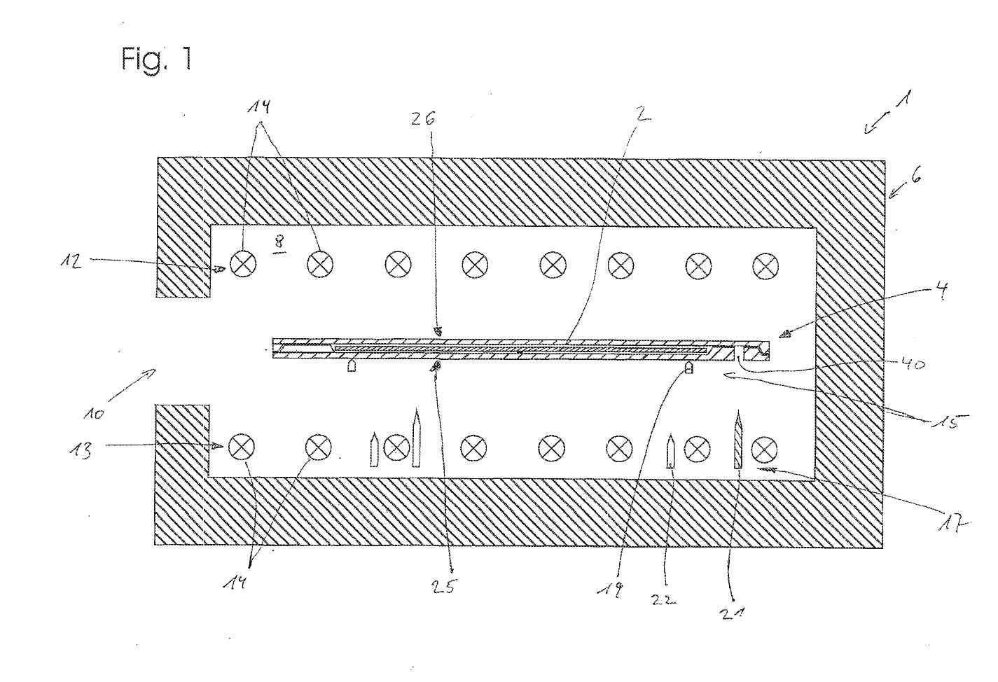

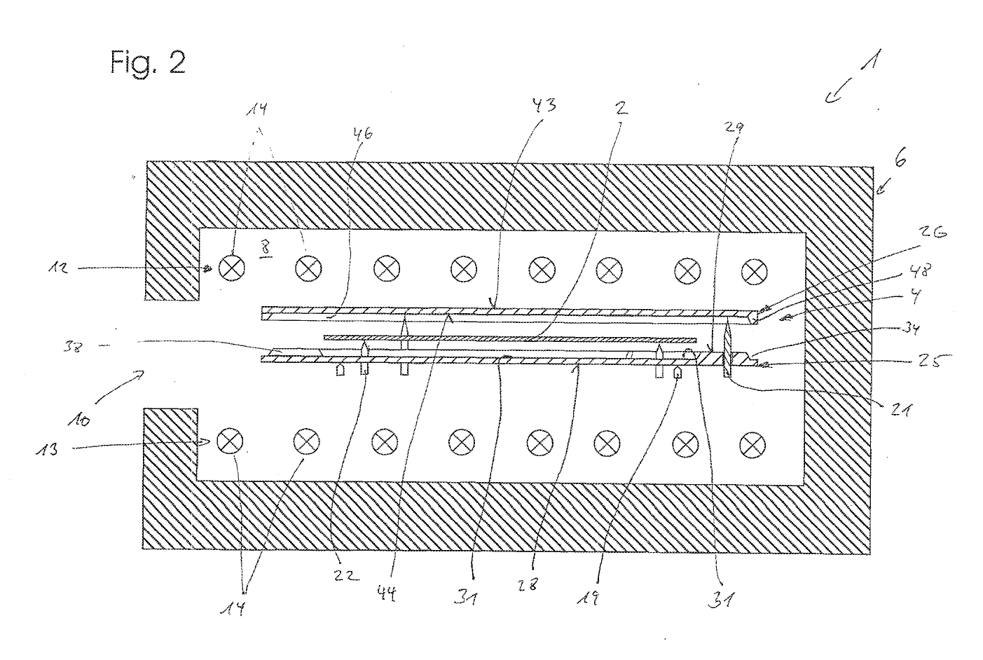

FIGS. 1 and 2 show schematic cross-sectional views of an apparatus 1 for the thermal treatment of substrates 2 having a receiving unit 4 received therein. FIG. 1 shows the receiving unit 4 in a closed state within the apparatus 1 and FIG. 2 shows the receiving unit 4 in an open state.

The apparatus 1 has a housing 6, which has a process chamber 8 in its interior. The housing 6 has a loading/unloading opening 10 which can be closed by a door mechanism, not shown. In the housing at least one gas inlet opening and a gas exhaust opening, both of which are not shown are provided. The gas inlet opening and the gas exhaust opening communicate with the process chamber 8 in a known manner. In particular, at least one gas supply opening is formed in a first side wall of the housing 6 and at least one gas exhaust opening is formed in the opposite housing side wall, in order to allow a substantially straight flow through the process chamber 8.

An upper row of lamps 12 and a lower row of lamps 13 are arranged in the process chamber 8, each of which has a plurality of heating lamps 14, such as, for example, tungsten halogen lamps and/or arc lamps. However, other suitable lamps can also be used. Although not shown, the upper row of lamps 12 and the lower row of lamps 13 may be separated from a central processing area by a cover which is substantially transparent to the radiation of the lamps 14, such as a quartz plate, as is known in the art. The inner walls of the process chamber 8 have a mirror like surface to direct substantially the entire radiation of the heating lamps 14 towards the central processing area.

The support 15 has of a plurality of support pins 19, which are arranged such that they arrange a closed receiving unit 4, substantially centered between the upper row of lamps 12 and the lower row of lamps 13. The support pins 19 are preferably made of a material which is transparent to the radiation of the heating lamps, such as quartz, but they may also consist of another suitable material. The support pins 19 may be arranged stationary within the process chamber or they may be connected to a lifting device.

A lifting unit 17 has of a plurality of cover support pins 21 and a plurality of substrate support pins 22, whose function will be explained in more detail herein below. The support pins 21, 22 of the lifting unit 17 are movable in the vertical direction via a lifting mechanism, not shown, such as a circular lifting mechanism. Alternatively, the support pins 21, 22 could also be stationary if the support pins 19 are movable. The support pins 21, 22 are again preferably made of material, which is transparent or substantially transparent to the radiation of the heating lamps, such as quartz.

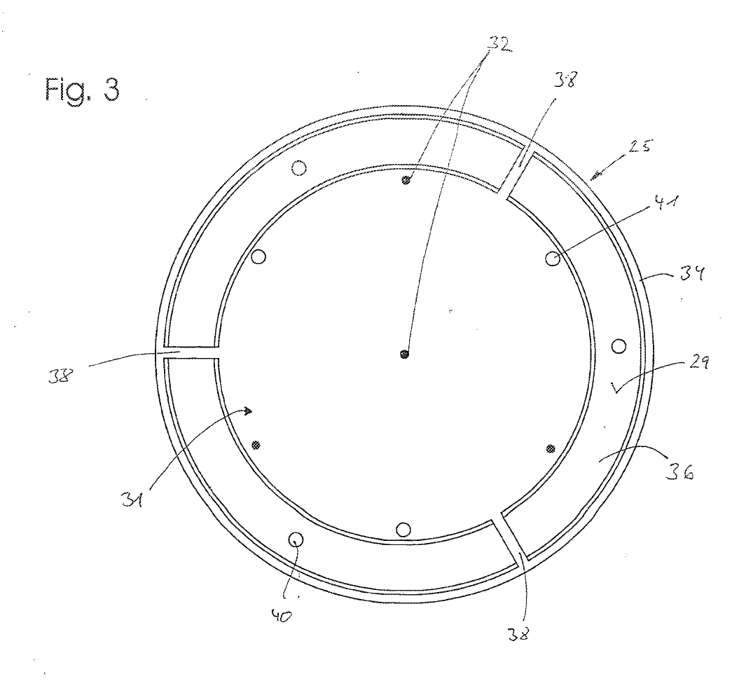

The receiving unit 4 for the substrate 2 is in substance formed by of a base or base 25 and a cover 26, which in a closed state form a receiving space for the substrate 2 therebetween. FIG. 3 shows a schematic top view onto the base 25 of the receiving unit 4, which is shown in FIGS. 1 and 2. The base 25 is made of a material absorbing the radiation of the heating lamps, such as, for example, graphite or another highly absorbent material, which moreover does not impair the thermal treatment of the substrates, in particular does not introduce impurities into the treatment process.

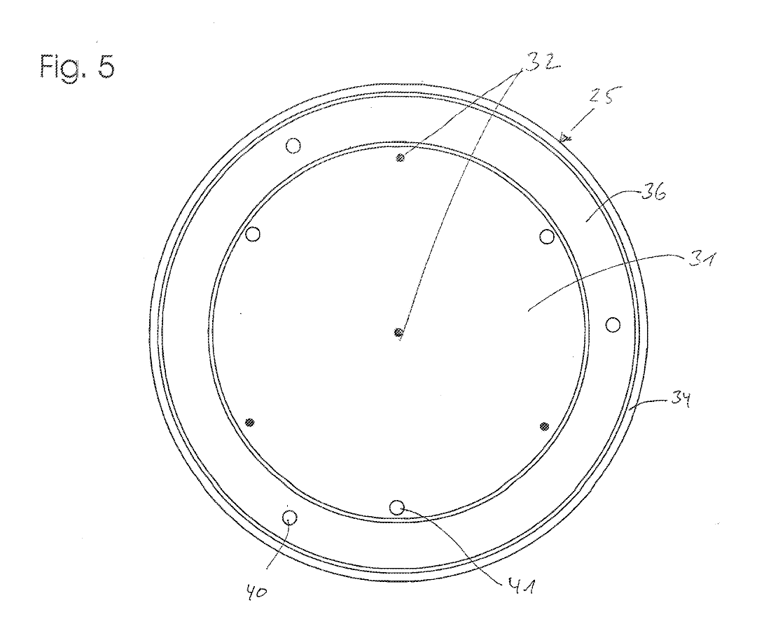

The base 25 is a plate element having a flat lower surface 28 and a contoured upper surface 29. In particular, a recess 31 is formed in the upper surface 29, which has a height which is greater than the thickness of a substrate 2 to be accommodated. In the region of the recess 31, a plurality of support pins 32 is provided, which are suitable for supporting the substrate 2 closely spaced to the upper surface 29 of the base 25 in the recess 31. In the illustration of FIG. 5, four of these support pins are shown, namely a central support pin and three edge support pins, which are each offset by 120° to each other. But it is also possible to provide a different arrangement of support pins 32. The support pins 32 have a height that is designed so that a substrate 2 resting thereon does not project beyond an upper edge of the recess. Thus, the combined height of the height of the support pins 32 and the thickness of a substrate 2 to be received is smaller than the depth of the recess 31. However, it would also be possible for a substrate 2 accommodated in the recess 31 to project beyond the upper edge of the base 25 if a respective receiving space for the substrate were provided in the cover 26.

In the edge region of the upper side 25, a further optional recess 34 is provided which, for example, has a depth corresponding to the depth of the recess 31. The recess 34 is fully encircling the central recess, such that between the recess 34 and the central recess 31, an annular web 36 is formed.

A plurality of channels having a depth corresponding to the depth of the recess 34 and the recess 31 is formed in the web 36. For example, as can be seen in the plan view according to FIG. 3, three such channels 38 are provided. As will be explained in more detail herein below, the channels 38 serve to allow a purging of the receiving space of the receiving unit 4 even in the closed state of the receiving unit 4. The channels 38 are arranged offset by 120° to each other in the circumferential direction and extend radially in the direction of a center of the base 25. The channels 38 each preferably have a length, which is at least three times greater than the other dimensions of the channel, i.e. the height or width of the channel 38. Hereby, a passage of radiation through the channel is essentially prevented, as will be explained in more detail herein below.

Moreover, a plurality of through-openings is provided in the base 25, which connect the lower surface 28 and the upper surface 29. A group of first through-openings 40 is formed in the region of the web 36, while a group of second through-openings 41 is formed in the region of the recess 31. As shown, three through-openings are provided in each group, which are arranged offset by 120° to each other in the circumferential direction of the base. As the person skilled in the art can recognize, a larger number of through-openings may also be provided, whereby the arrangement of the respective through-openings may also differ from the form as shown. The first through-openings 40 are each dimensioned for receiving the first support pins 21 and letting them pass therethrough, and the first through-openings 40 may be aligned with the first support pins 21. The second through-openings 41 are each dimensioned for receiving the second support pins 22 and may be aligned with the same. Thus, the number of the support pins 21 corresponds to the number of the first through-openings 40 and the number of the support pins 22 corresponds to the number of the second through-openings 41.

The cover 26 has a flat upper surface 43 and a contoured lower surface 44. The lower surface 44 has a central recess 46 which is formed such that only a peripheral edge web 48 remains, which is in substance complementary to the recess 34 in the upper surface 29 of the base 25. A plurality of passages is provided in the edge web 48, which are provided complementary to the channels 38 in the web 36 of the base 25, and which are aligned with the same. In particular, alignment marks or alignment structures may be provided on at least one of the base 25 and the cover 26, which ensure proper alignment of the base 25 and the cover 26 to ensure alignment of the passages in the edge web 48 with the channels 38 in the web 36 of the base 25. With a respective alignment, it would be possible to allow purging of the receiving space of the receiving unit 4 even in the closed state of the receiving unit 4. By placing the cover 26 in a rotated fashion on the base 25, a substantially completely closed receiving space is formed, at least in such a way that there is no opening extending from the edge area to the receiving space, which may be desirable in certain applications.

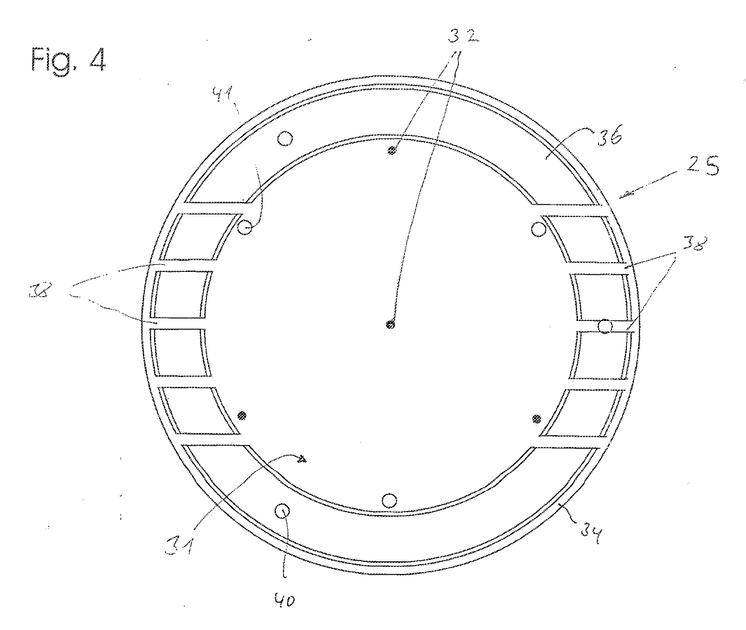

FIG. 4 shows a schematic top view onto an alternative base 25 of the receiving unit 4. In FIG. 4, the same reference numerals are used as in the previous embodiment, as long as the same or similar elements are designated. The base 25 is substantially similar to the base 25 described above and again has a central recess 31 and a plurality of support pins 32 in the recess 31. An edge recess 34 is also provided, so that a web 36 is formed. Again, a plurality of channels 38 is formed in the web 36, but the number and orientation of the channels 38 is different from the number and arrangement of the channels 38 according to the previous embodiment. In the embodiment according to FIG. 4, a total of ten channels 38 is provided, namely five on the left side and five on the right side. The channels 38 each extend parallel to one another and the channels on the left side (according to the top view of FIG. 4) are aligned with the channels 38 on the right side. Of course, an even larger or a smaller number of respective channels 38 may be provided and the channels on the opposite sides may be offset.

As the person skilled in the art can see, the cover 26 in this embodiment must be adapted accordingly, so that a corresponding number of openings is provided in the edge web 48, which can be aligned with the channels 38. Again, an offset placement of the cover 26 (for example, rotated by 90°) is possible in order to provide a substantially closed receiving space.

The channels 38 are each shown as straight channels in the above embodiments. However, it is also possible that the channels 38 do not have a straight shape, but for example, have a Y configuration. Such a configuration could prevent radiation from passing through the corresponding channels 38 onto a substrate 2 in the recess 31 even is the respective channels 38 have a shorter length. Such a Y configuration may be formed either within the plane of the web 36 such that a left/right distribution of a gas flow into the receiving space occurs. The Y configuration could also be designed so that a distribution of the gas flow is achieved in upwards or downwards direction in order to generate a directed gas flow above or below a substrate 2 received in the recess 31.

FIG. 5 shows a schematic top view onto a further embodiment of the base 25 of the receiving unit 4. Again, the same reference numerals are used as before. The base 25 again has a central recess 31, having a plurality of support pins 32 provided therein. Also, again, an edge recess 34 is provided, so that a web 36 is formed between the recess 34 and the recess 31. In this embodiment, however, the web 36 is fully circumferential, i.e. no channel 38 is provided. Accordingly, the cover 26 should also not have openings or passages in the region of the edge web 38. Such a combination of base and cover would provide a substantially closed receiving space within the receiving unit.

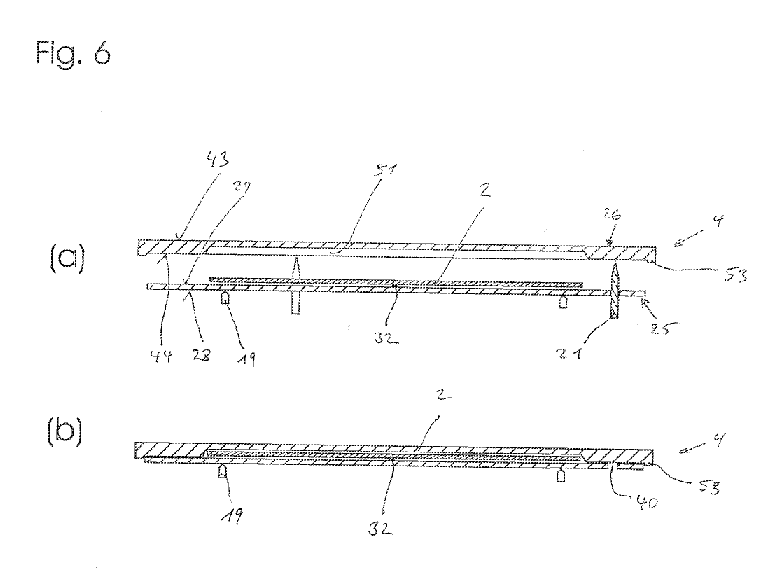

FIG. 6 shows an alternative embodiment of the receiving unit 4, again using the same reference numerals as in the previous embodiments.

The receiving unit 4 again has a base 25 and a cover 26. In this embodiment, however, the base 25 is a substantially flat plate without contoured lower surface or contoured upper surface. However, support pins 32 are provided on the upper surface, of which only a central support pin 32 can be seen in the illustration. In the edge region, plurality of through-openings 40 is provided are arranged radially outside a receiving area for the substrate 2. One of these through-openings 40 is shown on the right in FIG. 6. Further through-openings (at least two more) are distributed in the circumferential direction of the base 25.

The cover 26 differs substantially from the cover 26 of the previous embodiments, in that here the cover 26 has a central recess 51 in a lower surface 44 of the cover 26. The upper surface 43 of the cover 26 is again flat. The central recess 51 forms a receiving space for the substrate and is dimensioned accordingly. The recess 51 is in particular dimensioned such that in the closed state of the receiving unit 4, the lower surface 44 of the cover 26 is located closely spaced to the upper surface of the substrate 2 and sidewalls of the recess closely surround the substrate 2. Furthermore, in this embodiment, the cover 26 has a larger circumference than the base 25, so that the cover 26 protrudes radially beyond the base 25. In the edge region of the cover 26, a raised rim 53 is provided at the lower surface, which at least partially surrounds the base in the closed state, as can be seen in FIG. 6b. The area between the raised rim 53 and the recess 51 on the lower surface 44 of the cover 26 is the part which rests on the base 25 in the closed state of the receiving unit 4. As shown in the figures, the respective area of the base (web 36) (FIGS. 1-5) or the upper part (FIG. 6) surrounding the substrate 2 in the closed state of the receiving unit 4 is relatively wide, which is due to the fact that the respective area is designed as an edge protection element. This element virtually increases the circumference of the substrate 2 to suppress edge effects at the edge of the substrate 2 during the thermal treatment of the same. Because an almost continuous material characteristic is provided in the substrate plane, edge effects which may occur (increased heating during heating, faster cooling during cooling) are transferred to the edge regions of the receiving unit 4.

In the embodiment according to FIG. 6, it is possible, to thoroughly purge the receiving space, even without lifting the substrate 2, when the cover 26 is lifted off as shown in FIG. 6 a. Respective passage openings in the base 25 can therefore be omitted. For loading and unloading of the substrate 2, it can be handled either via an edge gripper or via a gripper which moves between the base 25 and the substrate 2. Thus, a substantially hermetically closed receiving space may be formed between the base 25 and cover 26.

Herein below, a thermal treatment of a substrate 2 within the apparatus 1 will be explained in more detail.

First, the receiving unit 4 and the substrate 2 are loaded into the process chamber 8 of the thermal treatment apparatus 1. In this case, the substrate may have been loaded outside of the process chamber 8 into the receiving unit 4, and the two may be loaded together into the process chamber 8. However, it would also be possible to first load the receiving unit 4 into the process chamber 8 and to open the same in the process chamber 8 via the support pins 21, as shown in FIG. 2, and to subsequently load the substrate 2 into the process chamber 8. The substrate 2 could then be placed on raised support pins 22. At present, however, it is preferred to introduce the receiving unit 4 together with the substrate 2 already received therein into the process chamber 8. After loading the receiving unit and the substrate, the process chamber 8 is closed.

Now, the receiving unit 4 can be purged with a desired gas, such as an inert gas or even a process gas to purge the receiving space within the receiving unit in which the substrate 2 is received, and if needed, to set a desired atmosphere. In particular, for example, O₂ can be purged or flushed out, which is for example required for WBG substrates. The purging—in the embodiment of the receiving unit having the purge openings (for example, according to FIG. 1 to FIG. 4)—can be performed with the receiving unit being in the closed state. However, it is also possible to open the receiving unit 4 during the purging process, by raising the support pins 21 in order to lift the cover 26 off the base 25. Optionally, also the substrate can be lifted off via the support pins 22 in order to be able to better purge the area between the substrate 2 and the base 25. For purging a gas may simply be passed through the process chamber 8, by for example introducing a gas on one side of the process chamber 8, which is exhausted (pumped out) on the opposite side. By appropriate arrangement of a gas supply and a gas evacuation unit, a substantially laminar or straight line gas flow through the process chamber 8 may be achieved.

Preferably, however, a purge cycle is provided, which comprises an evacuation of the process chamber to a negative pressure, followed by the introduction of at a purge gas and/or a process gas with simultaneous exhaustion of the same. By evacuating the process chamber to a negative pressure, there is an improved distribution of the purge gas within the process chamber and in particular in the region of the receiving space in the receiving unit 4. This is especially true in the case where the receiving unit 4 is not opened for purging. To set a desired gas atmosphere in the receiving space, a plurality of such purge cycles consisting of evacuating the process chamber to a negative pressure with subsequent introduction of a purge gas or a process gas can be used.

If the receiving unit 4 was opened during purging, as shown in FIG. 2, which of course would also be required in the embodiment of FIG. 5 or FIG. 6, the receiving unit 4 is again closed. Thereafter, the receiving unit 4 is heated by the heating lamps 14 and thus the substrate 2 is heated within the receiving unit. When a receiving unit 4 having respective purge openings (channels) is used, a gas flow through the receiving space can be continuously maintained during the thermal treatment, if so desired. In this case, a purge gas can be used to remove, for example, substances which are outgassing from the base 25 or cover 26, or a process gas could also be introduced. In this case, the flow should be set sufficiently low that it has no effect on the thermal treatment, i.e. no temperature inhomogeneities are generated by the gas flow.

When using a closed receiving unit according to FIG. 5 or also according to FIG. 6, a respective flow of gas would not be expedient during the thermal treatment. Such a closed receiving unit, which can for example be used for GaAs processes, the receiving unit, i.e. the upper surface of the base and/or the lower surface of the cover may be saturated with arsenic to release arsenic during the thermal treatment and to set an arsenic vapor pressure within the closed receiving unit 4 which prevents arsenic from diffusing out of the GaAs substrate.

The invention has been explained in detail above with reference to preferred embodiments of the invention, without being limited to the specific embodiments.

In particular, the structure of the apparatus 1 for thermal treatment can differ from that shown in the drawings. In particular, the lifting unit 17 having the support pins 21 and 22 could be dispensed with, when opening of the receiving unit 4 within the process chamber 8 is not desired or not required. It is also possible to use a different base or cover for the receiving unit 4, which, however, have to form a receiving space for the substrate 2 therebetween. Different configurations are possible. For example, it would also be conceivable to provide purge openings in the cover 26, for example in the embodiment according to FIG. 6. Here, for example, respective channels could be provided in the contact area of the cover. For an improved sealing between the cover 26 and the base 25, it would be possible to provide a seal. It would also be possible, for example, instead of one element (base or cover) radially surrounding the other (cover or base) as shown in the embodiments to provide an engagement between the base 25 and cover 26. This could for example be achieved by one of the base and the cover having a circumferential web which engages a respective circumferential groove in the other one of the base and the cover. The person skilled in the art will recognize various different embodiments. Also, different materials can be used for the base 25 and the cover 26, which on the one hand absorb the radiation of the heating lamps 14 and on the other hand do not provide contaminations for the substrate to be treated.

As mentioned earlier, graphite is considered to be a suitable material that for example does not introduce contaminations in semiconductor processes. The graphite may be present in normal form or, in particular, as a pyrolytically coated graphite, which for example may furthermore be saturated with arsenic for the treatment of GaAs substrates. Furthermore, in particular, silicon carbide or silicon carbide-coated graphite is also considered as a suitable material. In particular, silicon carbide-coated graphite can be manufactured inexpensively for the process and has suitable properties. Also other materials such as boron nitride or boron nitride coated graphite are considered as a suitable material.

In order to promote outgassing of elements from the receiving unit before and/or during the purging process, the base 25 and the cover can be heated slightly, wherein the heating must be kept low enough such that there is no substantial increase in the reactivity with the substrate. In any case, such a heating prior to and/or during the purging process is substantially below the process temperature. Such heating can be achieved for example by pulsed control of the lamps and is possible both with an open and a closed receiving unit.

1-14. (canceled)

15. A method for thermally treating a substrate in a processing unit having a process chamber and a plurality of radiation sources, wherein the substrate is received in a box having a base and a cover forming a receiving space for the substrate therebetween, the method comprising the steps of:
loading the box and the substrate into the process chamber and closing the same;
purging the receiving space of the box with at least one of a purge gas and a process gas prior to heating the box and the substrate therein to a desired process temperature in order to set a desired atmosphere within the box;
heating the box and the substrate therein to the desired process temperature by means of thermal radiation emitted by the radiation sources.

16. The method of claim 15, wherein the box has a plurality of purge openings connecting a circumference of the box to the receiving space to permit purging of the receiving space in the closed state of the box, the purge openings being configured to prevent the passage of thermal radiation emitted by the radiation sources.

17. The method according to claim 15, wherein for purging the receiving space, the box is opened within the process chamber.

18. The method according to claim 15, wherein for purging the receiving space, the substrate is lifted up from the base of the box.

19. The method of claim 17, wherein the base has a substantially flat configuration and a plurality of support pins to hold the substrate spaced from the upper surface of the base, and wherein the cover has a recess in which the substrate is received when the box is in the closed state.

20. The method according to claim 15, wherein the purging comprises at least one purge cycle which comprises exhausting the process chamber to a negative pressure and subsequently introducing at least one of a purge gas and a process gas.

21. The method of claim 20, wherein the method comprises a plurality of purge cycles.

22. A receiving unit for a substrate for supporting the substrates in a process unit having a process chamber and a plurality of radiation sources, the receiving unit having a base and a cover which in a closed state form a box with a receiving space for the substrate therebetween, wherein at least one of the base and the cover has a plurality of purge openings connecting a circumference of the box to the receiving space to allow purging of the receiving space in the closed state of the box, wherein the purge openings are configured to in substance prevent passage of thermal radiation emitted by the radiation sources.

23. The receiving unit according to claim 22, wherein the purge openings have a length which is at least three times longer than their width or height.

24. The receiving unit according to claim 22, wherein the purge openings do not extend straight through the respective part in which they are formed.

25. The receiving unit according to claim 24, wherein the purge openings have a Y-configuration.

26. Apparatus according to claim 22, wherein the base and the cover have complementary circumferential structures which engage each other in the closed state of the box or a structure where one portion of the base or cover radially surrounds the other.

27. An apparatus for thermally treating substrates, the apparatus comprising:
a process chamber;
a plurality of radiation sources;
a receiving unit having a base and a cover which, when closed, form a box with a receiving space for the substrate therebetween; and
a support unit for supporting the box in the process chamber;
wherein at least one of the following is conditions is met;
at least one of the base and cover of the receiving unit has a plurality of purge openings which connect a circumference of the box to the receiving space to allow purging of the receiving space in the closed state of the box, wherein the purge openings are formed so as to substantially prevent the passage of thermal radiation emitted by the radiation sources, and
the apparatus comprises a unit for opening the receiving unit within the process chamber to allow purging of the receiving space within the process chamber.

28. The apparatus according to claim 27, wherein the receiving unit has a base and a cover which in a closed state form a box with a receiving space for the substrate therebetween, wherein at least one of the base and the cover has a plurality of purge openings connecting a circumference of the box to the receiving space to allow purging of the receiving space in the closed state of the box, wherein the purge openings are configured to in substance prevent passage of thermal radiation emitted by the radiation sources.

29. The apparatus of claim 27, wherein the base of the receiving unit has a substantially flat configuration having a plurality of support pins for holding the substrate spaced from the upper surface of the base, and wherein the cover has a recess in which the substrate is received in a closed state of the box.

30. The apparatus according to claim 27, wherein the base and the cover have complementary circumferential structures which engage in the closed state or a structure where one portion of the base or cover radially surrounds the other.
